(19) United States
(12) Patent Application Publication
(10) Pub. No.: US 2010/0107970 A1
(43) Pub. Date: May 6, 2010

(54) SILICA GLASS CRUCIBLE HAVING MULTILAYERED STRUCTURE

(75) Inventors: Makiko KODAMA, Akita (JP); Masaki MORIKAWA, Akita (JP)

Correspondence Address: GREENBLUM & BERNSTEIN, P.L.C., 1950 ROLAND CLARKE PLACE, RESTON, VA, 20191, US

(73) Assignee: JAPAN SUPER QUARTZ CORPORATION, Akita-ken (JP)

(21) Appl. No.: 12/351,207

(22) Filed: Jan. 9, 2009

(30) Foreign Application Priority Data
Oct. 31, 2008 (JP) 2008-281169

(51) Int. Cl. C30B 15/10

(52) U.S. Cl. 117/208

(57) ABSTRACT

Disclosed is a silica glass crucible employed in pulling silicon single crystals. The crucible comprises at least a transparent layer, semitransparent layer, and opaque layer disposed from the inner surface side to the outer surface side of the crucible. The content of bubbles in the transparent layer is less than 0.3 percent; the content of bubbles in the semitransparent layer falls within a range of from 0.3 to 0.6 percent; and the content of bubbles in the opaque layer is greater than 0.6 percent.

### CROSS-REFERENCE TO RELATED APPLICATIONS

This application claims benefit of priority under 35 USC 119 to Japanese Patent Application No. 2008-281169 filed on Oct. 31, 2008, which is expressly incorporated herein by reference in its entirety.

### BACKGROUND OF THE INVENTION

1. Field of the Invention

The present invention relates to a silica glass cruciblesilica glass crucible having a multilayered structure that is employed in the pulling of silicon single crystals for use as semiconductor materials.

2. Discussion of the Background

In the silica glass crucibles employed in the pulling of silicon single crystals, the quality of the inner surface coming in contact with the silicon melt greatly affects the pulling yield and the quality of the crystals that are pulled. In particular, when bubbles are present in the vicinity of the inner surface of the crucible walls (peripheral wall and bottom wall) that come into contact with the silicon melt, the single crystallization yield (single crystallization rate) is known to decrease. Thus, it is necessary for the inner surface of a silica glass crucible to be a transparent, pure glass layer containing as few bubbles and impurities as possible. This inner surface is often formed out of synthetic quartz containing few impurities.

The rotating mold method is currently the mainstream method of manufacturing silica glass crucibles. In this method, quartz powder serving as the starting material is deposited by centrifugal force on the inner surface of a crucible-shaped mold that is being rotated, and the quartz powder that has been deposited on the rotating mold is fused and vitrified by arc discharge heating to mold it into the shape of a crucible. In this case, the following two methods are known for forming high-purity transparent quartz layers with few bubbles on the inner surface of a crucible. In the first method, the quartz layer is aspirated under reduced pressure from the mold side during arc fusion of the quartz powder; in the course of vitrification by fusing the quartz powder, the quartz layer is subjected to reduced pressure to aspirate bubbles from the interior out to the exterior to form a transparent glass layer containing few bubbles (Japanese Unexamined Patent Publication (KOKAI) Heisei Nos. 01-157426, 01-160836, and the like). In the second method, quartz powder is fused by being passed through an arc, and the fused quartz powder is laminated on the inner surface of a premolded silica glass crucible to form a transparent glass layer (Japanese Unexamined Patent Publication (KOKAI) Heisei No. 01-148718, U.S. Pat. Nos. 4,935,046 and 4,956,208, the English family thereof, and the like). Either of these methods permits the manufacturing of a silica glass crucible with a synthetic quartz layer of high purity on the inner surface thereof when synthetic quartz powder of high purity is employed.

In a silica glass crucible that is manufactured by the above rotating mold method, a high-purity, transparent quartz layer with few bubbles is formed on the inner surface of the crucible, and an opaque layer of higher bubble content than the transparent quartz layer is present on the outer surface side.

The size of the silicon single crystals that are manufactured by pulling with silica glass crucibles has been increasing in approximately ten-year cycles. It is desirable for device manufacturers to increase the size of the silicon single crystals and increase the size of the wafers that are cut from the silicon single crystals to enhance the efficiency of device manufacturing. For this reason, the manufacturing of silicon single crystals having diameters of about 1.5-fold the current diameter of 300 mm is anticipated in the near future.

As the size of the silicon single crystal increases, the size of the silica glass crucible will necessarily increase. To manufacture large silicon single crystals of high quality, it does not suffice to simply increase the size of the silica glass crucible. For example, achieving a homogenous large silicon single crystal requires rendering uniform the surface state of the inner surface of the silica glass crucible and uniformly heating the silica glass crucible.

In conventional silica glass crucibles having a transparent quartz layer on the inner surface thereof and having an opaque layer on the outside, there is variation in the thickness of the transparent quartz layer and the opaque layer. This variation in thickness prevents uniform heating of the silica glass crucible, resulting in localized variation in the temperature of the silicon melt. Even in the manufacturing (pulling) of the current silicon single crystals 300 mm in diameter, such variation affects the quality of the silicon single crystal. Accordingly, various silica glass crucibles have been proposed to maintain the quality of silicon single crystals. In these silica glass crucibles, used for pulling silicon single crystals, the portion of the wall on the inner surface side is comprised of a transparent glass layer that is substantially free of bubbles, and the portion of the wall on the outer surface side is comprised of an opaque glass layer containing numerous bubbles. Their structures and the like have various characteristics (Japanese Unexamined Patent Publication (KOKAI) Heisei Nos. 06-101986, 06-329493, 08-169798, and 09-157082).

However, in the manufacturing (pulling) of ever larger silicon single crystals as set forth above, the negative effects on the quality of the silicon single crystals increase. Even in the silica glass crucibles described in Japanese Unexamined Patent Publication (KOKAI) Heisei Nos. 06-191986, 06-329493, 08-169798 and 09-157082, there is a problem in that it is difficult to maintain the quality of the silicon single crystals.

Accordingly, the present invention, devised to solve the above-described problem, has for its object to provide a silica glass crucible permitting the manufacturing (pulling) of homogenous silicon single crystals by inhibiting localized variation in the temperature of the silicon melt, even when manufacturing (pulling) large silicon single crystals.

### SUMMARY OF THE INVENTION

The present invention relates to a silica glass crucible employed in the pulling of silicon single crystals, characterized by comprising at least a transparent layer, semitransparent layer, and opaque layer disposed from the inner surface side to the outer surface side of the crucible; in that the content of bubbles in the transparent layer is less than 0.3 percent; in that the content of bubbles in the semitransparent layer falls within a range of from 0.3 to 0.6 percent; and in that the content of bubbles in the opaque layer is greater than 0.6 percent.

The present invention provides a silica glass crucible permitting the manufacturing (pulling) of homogenous silicon single crystals by inhibiting localized variation in the temperature of the silicon melt, even when manufacturing (pulling) large silicon single crystals. The present invention further provides a method for manufacturing the silica glass crucible of the present invention affording such advantages.

Other exemplary embodiments and advantages of the present invention may be ascertained by reviewing the present disclosure and the accompanying drawings.

### BRIEF DESCRIPTION OF THE DRAWINGS

The present invention will be described in the following text by the exemplary, non-limiting embodiments shown in the figures, wherein:

FIG. 1 shows a conceptual sectional view of a conventional silica glass crucible and a conceptual sectional view of the silica glass crucible of the present invention.

FIG. 2 shows a sectional photograph of a silica glass crucible manufactured in an embodiment (right). The figure in the middle is an enlarged conceptual sectional view of the silica glass crucible.

FIG. 3 shows the relation between the thickness ratio (semitransparent layer:opaque layer) and the single crystal yield for quartz crucibles 18 inches in size (Embodiments 3 to 5 and Comparative Example 1).

FIG. 4 shows the relation between the presence or absence of a semitransparent layer and the single crystal yield for quartz crucibles 18 inches, 24 inches, and 32 inches in size (Embodiment 4 and Comparative Example 1; Embodiment 7 and Comparative Example 2; and Embodiment 10 and Comparative Example 3).

### DESCRIPTIONS OF THE EMBODIMENTS

The following preferred specific embodiments are, therefore, to be construed as merely illustrative, and not limitative of the remainder of the disclosure in any way whatsoever. In this regard, no attempt is made to show structural details of the present invention in more detail than is necessary for the fundamental understanding of the present invention, the description taken with the drawings making apparent to those skilled in the art how the several forms of the present invention may be embodied in practice.

The silica glass crucible of the present invention, employed in pulling silicon single crystals, is characterized by comprising at least a transparent layer, semitransparent layer, and opaque layer disposed from the inner surface side to the outer surface side of the crucible; in that the content of bubbles in the transparent layer is less than 0.3 percent; in that the content of bubbles in the semitransparent layer falls within a range of from 0.3 to 0.6 percent; and in that the content of bubbles in the opaque layer is greater than 0.6 percent.

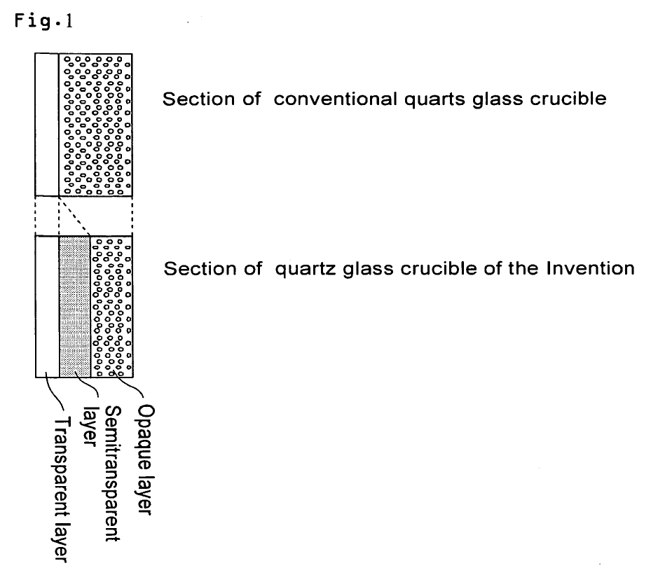

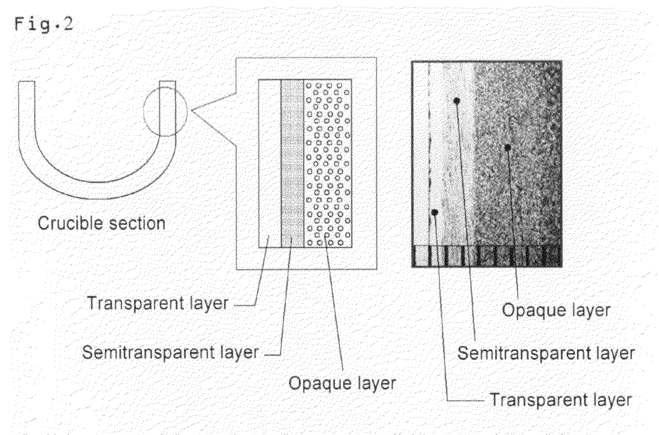

As shown in FIG. 1, a conventional silica glass crucible is comprised of just a transparent layer and an opaque layer (upper figure). However, the silica glass crucible of the present invention is comprised of at least a transparent layer, semitransparent layer, and opaque layer (lower figure).

Since the silica glass crucible of the present invention comprises the above transparent layer, semitransparent layer, and opaque layer, the heating characteristics of the silica glass crucible are enhanced, and localized variation in the temperature of the silicon melt within the crucible due to heating from outside the silica glass crucible is inhibited. As a result, for example, it is possible to manufacture homogenous silicon single crystals, even when manufacturing silicon single crystals having a diameter of about 1.5 times the current diameter of 300 mm.

The transparent layer has a bubble content of less than 0.3 percent, desirably a bubble content of 0.1 percent, and preferably a bubble content of 0.05 percent or less. When bubbles are internally contained in the vicinity of the inner surface of the crucible walls, the bubbles in the interior thermally expand during pulling, causing the inner surface of the crucible to partially separate, causing bubbles and small pieces of separated quartz to enter the silicon single crystal and induce polycrystallization, and diminishing the single crystallization yield (single crystallization rate). Accordingly, in the present invention, the content of bubbles in the transparent layer is desirably as low as possible.

In the semitransparent layer, the bubble content falls within a range of from 0.3 to 0.6 percent, desirably within a range of from 0.35 to 0.55 percent, and preferably within a range of from 0.4 to 0.5 percent.

In the opaque layer, the bubble content is greater than 0.6 percent, desirably 1.0 percent or greater, and preferably 3.0 percent or less.

In the transparent layer, the thickness of the bottom portion of the crucible, for example, falls within a range of 0.5 to 10 mm. The thickness of the transparent layer in the bottom portion of the crucible desirably falls within a range of 2 to 5 mm.

The combined thickness of the semitransparent and opaque layers, for example, falls within a range of 5 to 50 mm. The combined thickness of the semitransparent and opaque layers desirably falls within a range of 10 to 50 mm. However, the combined thickness of the semitransparent and opaque layers can be suitably determined in consideration of the strength required of the crucible as a function of the size of the silica glass crucible, and the like.

The ratio of the thicknesses of the semitransparent and opaque layers (semitransparent layer:opaque layer) falls, for example, within a range of from 5:95 to 95:5, desirably within a range of from 15:85 to 50:50, and preferably, within a range of from 20:80 to 40:60.

As set forth above, there are desirably as few bubbles as possible in the inside portion of the crucible so as to reduce the negative effect during the pulling of silicon single crystals. However, bubbles in the outer peripheral portion do not negatively affect pulling; naturally, an opaque layer that tends not to transmit infrared heat is suited to achieving an insulating effect during heating. The opaque layer is also advantageous in that it permits the achieving of a uniform temperature distribution due to greater propagation of heat by diffusion than the transparent layer. Thus, the outer peripheral side portion of the crucible is in the form of an opaque glass layer containing a large number of bubbles.

As the diameter of crucibles has increased, there has been a tendency to increase the thickness of the peripheral wall and bottom of the crucible to maintain strength. On the other hand, due to manufacturing limitations, it is difficult to exceed a certain transparent layer thickness. Thus, as the diameter of crucibles has increased, the thickness of the opaque layer has increased. However, as set forth above, the opaque layer tends not to transmit infrared radiation. Thus, it has a good insulating effect. However, this is a drawback from the perspective of effectively heating the interior of the crucible.

Accordingly, an opaque layer and a semitransparent layer that is provided between the opaque layer and the transparent layer are provided in the present invention, permitting effective heating by a heating means positioned outside the crucible. The insulating effect of this structure is also good. As a result, a high crystallization rate is achieved during the pulling of silicon single crystals.

From this viewpoint, and taking into account the combined thickness of the semitransparent layer and opaque layer, the thickness ratio of the semitransparent layer and the transparent layer is suitably selected so as to fall within the above range of from 5:95 to 95:5. The larger the proportion of the semitransparent layer becomes, the more efficiently the interior of the crucible can be heated, and the lower the insulating effect becomes. However, approximately the same insulating effect can sometimes be achieved when at least an opaque layer in a certain thickness is present; the relation between the proportion of the semitransparent layer and the insulating effect is also affected by the combined thickness of the semitransparent layer and the opaque layer.

### [Method of Manufacturing a Silica Glass Crucible]

The silica glass crucible of the present invention is manufactured by the rotating mold method. In this method, starting material quartz powder or quartz glass powder (sometimes referred to simply as “starting material powder” hereinafter) for forming the transparent layer, semitransparent layer, and opaque layer is deposited on the inner surface of a hollow mold for forming a silica glass crucible, after which a state of reduced pressure is generated from the inner surface toward the outer surface of the hollow mold through passages formed in the inner portion of the hollow mold, and the starting material quartz or quartz glass powder that has been deposited is fused by heating to prepare a silica glass crucible.

The starting material powder can be natural or synthetic (crystalline) quartz or quartz glass powder.

In manufacturing by the rotating mold method, starting material powder is deposited on the inner surface of a rotated hollow mold; a means of heating such as arc discharge is used to vitrify the starting material powder by heating it; interior bubbles in the starting material powder layer are aspirated away from the mold side during this heating to achieve transparent vitrification; the reduced pressure aspiration period, heating and fusion period, and the like are controlled to adjust the content of bubbles in the transparent layer; and glass layers containing bubbles in the form of a semitransparent layer and opaque layer are obtained on the outside.

The starting material powder that is deposited, which is identical for the semitransparent layer and opaque layer, has a volumetric ratio of particles of 352 micrometers or less in size of 95 percent or greater, and a volumetric ratio of particles of 75 micrometers or less in size of 1.5 to 5 percent (referred to as “starting material powder A” hereinafter). The starting material quartz powders or quartz glass powders that are deposited to form the semitransparent layer and opaque layer desirably have the same particle size distribution. For the transparent layer, the starting material powder that is deposited has a volumetric ratio of particles 352 micrometers or less in size of 95 percent or greater, and a volumetric ratio of particles of 75 micrometers or less in size of 0 to less than 1.5 percent (referred to as “starting material powder B” hereinafter).

Starting material powder B is the starting material powder that is conventionally employed to manufacture crucibles having a transparent layer and an opaque layer. By contrast, no transparent layer can be formed by the conventional method when an attempt is made to fabricate a crucible having a transparent layer and an opaque layer using just starting material powder A.

When starting material B is employed in the transparent layer and starting material A is employed in the semitransparent and opaque layers, it is possible to form a transparent layer, semitransparent layer, and opaque layer by fusion by heating in about the same time and in about the same state of reduced pressure as by the conventional method.

Starting material powders A and B both equally contain a 95 percent or greater volumetric ratio of particles 352 micrometers or less in size, but differ in that the volumetric ratio of particles 75 micrometers or less in size is 1.5 to 5 percent and 0 to less than 1.5 percent, respectively. The particle size distribution of starting material powder A, which has a volumetric ratio of particles 75 micrometers or less in size of 1.5 to 5 percent, and that of starting material powder B, which has a volumetric ratio of particles 75 micrometers or less in size of 0 to less than 1.5 percent, are given in Table 1.

TABLE 1

| | | Maximum |
|---|---|---|
| | | volumetric ratio of any |
| | Volumetric ratio | single particle diameter |
| Starting material powder A | | |
| 75 micrometers or less | 1.5 to 5.0 | 2.5 |
| 148 micrometers or less | 25.0 to 40.0 | 20 |
| 250 micrometers or less | 70.0 to 90.0 | 20 |
| 352 micrometers or less | 95.0 to 99.0 | 20 |
| Starting material powder B | | |
| 75 micrometers or less | 0 to less than 1.5 | 1 |
| 148 micrometers or less | 5.0 to 25.0 | 15 |
| 250 micrometers or less | 50.0 to 80.0 | 25 |
| 352 micrometers or less | 95.0 to 99.0 | 30 |

(Unit: %)

Employing a starting material powder in the form of starting material powder A having a different particle size distribution than is conventionally employed permits the manufacturing of a crucible having a transparent layer, semitransparent layer, and opaque layer.

The above quartz crucible can be manufactured by the rotating mold method. In manufacturing by the rotating mold method, the starting material quartz powder is deposited on the inner surface of a hollow mold that is being rotated, and the quartz powder is vitrified by heating with a means of heating such as arc discharge. Bubbles within the quartz powder layer are aspirated away from the mold side during this heating to achieve transparent vitrification, and the reduced pressure aspiration period, heating and fusion period, and the like are controlled to adjust the bubble content. The portion on the outer surface side is still opaque glass containing numerous bubbles.

### Embodiments

The present invention will be described in greater detail below through embodiments.

### Embodiments 1 to 12

The quartz crucible of the present invention was manufactured by the rotating mold method as follows. First, starting material powder A was deposited on the inner peripheral surface of a rotating mold. Next, starting material powder B was deposited thereover. The particle size distribution of starting material powders A and B was as indicated in Table 2 below. Next, arc discharging was conducted from the inner peripheral surface side of the mold to fuse and vitrify the surface of the quartz layers. Simultaneously, the pressure was reduced from the mold side and the air in the quartz portion was aspirated to the outer peripheral side through air holes provided in the mold and exhausted to the outside through air holes to eliminate bubbles in the surface portion of the quartz layer, thus forming a transparent glass layer. Subsequently, the pressure reduction was halted and the heating was continued to form nontransparent layers in which bubbles remained in the form of a semitransparent layer and an opaque layer. The thickness ratio (semitransparent layer:opaque layer) and the infrared radiation transmittance of the sidewall portion, curved portion, and bottom portion of the quartz crucible obtained were as indicated in Table 3. The bubble content of the transparent layer, semitransparent layer, and opaque layer are also given in Table 3. Silicon single crystals were pulled using this quartz crucible. The results (single crystallization rate) are also shown in Table 3.

TABLE 2

Volumetric ratio (%)

| | Starting material | Starting material |
|---|---|---|
| | powder A | powder B |
| 75 micrometers or less | 2.39 | 0 |
| 148 micrometers or less | 31.51 | 9.59 |
| 250 micrometers or less | 80.88 | 59.4 |
| 352 micrometers or less | 97.46 | 97.04 |

The size of the quartz crucible was varied from 14 inches to 40 inches and the same testing was conducted. The results are given in Table 3. The bubble content given in Table 3 was measured by the following method. The bubble contents of the semitransparent layer and opaque layer were obtained by measuring the specific gravity. The bubble content of the transparent layer was measured by microscopic observation. The infrared radiation transmittance was measured by placing an infrared radiation powder meter with a heat-receiving surface of 1 cm² at a position 30 cm from an infrared radiation lamp with wavelengths of 0.5 to 3.5 micrometers and a peak wavelength of 1.0 micrometer, inserting a piece of crucible to be measured immediately in front of the heat-receiving surface, measuring the infrared radiation heat reception level, and calculating the transmittance using a heat reception level measured without the insertion of a piece of crucible as 100 percent. The average infrared radiation transmittance was the average of the values measured for each portion by this method. The single crystal yield was the ratio to a theoretical maximum single crystal yield of 100 percent.

TABLE 3

| | | Embodiment | | | | | | | | | | | |
|---|---|---|---|---|---|---|---|---|---|---|---|---|---|
| | | 1 | 2 | 3 | 4 | 5 | 6 | 7 | 8 | 9 | 10 | 11 | 12 |
| Size of crucible | | 14″ | 16″ | 18″ | 18″ | 18″ | 22″ | 24″ | 28″ | 30″ | 32″ | 36″ | 40″ |
| Thickness ratio (%) | | 40:60 | 40:60 | 5:95 | 35:65 | 50:50 | 35:65 | 35:65 | 35:65 | 35:65 | 35:65 | 35:65 | 35:65 |
| Semitransparent layer: opaque | | | | | | | | | | | | | |
| layer | | | | | | | | | | | | | |
| Bubble | Transparent | 0.05 | 0.05 | 0.05 | 0.05 | 0.05 | 0.05 | 0.05 | 0.05 | 0.05 | 0.05 | 0.05 | 0.05 |
| content (%) | Semitransparent | 0.4 | 0.4 | 0.5 | 0.5 | 0.5 | 0.5 | 0.5 | 0.5 | 0.5 | 0.5 | 0.6 | 0.7 |
| of layer | Opaque | 1.8 | 1.8 | 2.0 | 2.0 | 2.0 | 2.0 | 2.0 | 2.0 | 2.0 | 2.0 | 2.5 | 3.0 |
| Infrared | Wall portion | 68.5 | 67.4 | 58.3 | 65.9 | 70.9 | 64.7 | 60.7 | 57.4 | 56.9 | 53.3 | 53.1 | 50.3 |
| transmittance | Bend portion | 75.1 | 73.2 | 65.2 | 72.8 | 79.3 | 70.3 | 68.1 | 64.1 | 62.8 | 60.2 | 59.4 | 57.8 |
| (%) | Bottom portion | 62.2 | 60.9 | 53.1 | 59.8 | 65.2 | 57.1 | 54.9 | 50.8 | 50.1 | 48 | 46.6 | 46.2 |

| | | | | | | | | | | | | |
|---|---|---|---|---|---|---|---|---|---|---|---|---|
| Single crystal yield (%) | 88 | 90 | 79 | 95 | 83 | 87 | 89 | 90 | 89 | 96 | 93 | 90 |

### COMPARATIVE EXAMPLES 1 TO 3

Quartz crucibles that were 18 inches, 24 inches, and 32 inches in size were similarly fabricated using only starting material powder B and silicon single crystals were pulled. The results (single crystallization rates) are given in Table 4.

TABLE 4

| | | Comparative | | |
|---|---|---|---|---|
| | | Example | | |
| | | 1 | 2 | 3 |
| Size of crucible | | 18″ | 24″ | 32″ |
| Thickness ratio (%) | | 0:100 | 0:100 | 0:100 |
| Semitransparent layer: opaque layer | | | | |
| Bubble content of opaque layer | | 2.0 | 2.0 | 2.0 |
| Infrared | Wall portion | 56.7 | 62.3 | 49.2 |
| transmittance (%) | Bend portion | 64.1 | 63.7 | 52.3 |
| | Bottom portion | 51.8 | 50.6 | 46.7 |

| | | | |
|---|---|---|---|
| Single crystal yield (%) | 56 | 59 | 62 |

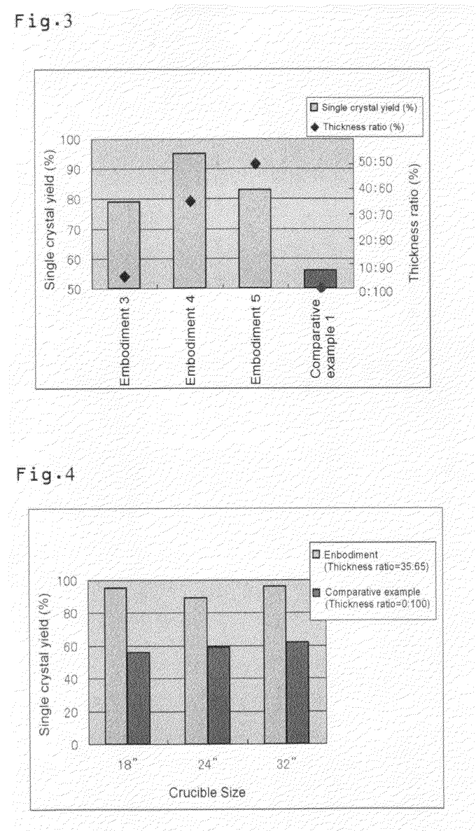

The relation between the proportions of the thickness ratio (semitransparent layer:opaque layer) and the single crystal yield of quartz crucibles that were 18 inches in size (Embodiments 3 to 5 and Comparative Example 1) are given in FIG. 3. The quartz crucible 18 inches in size that had a thickness proportion of 30 percent afforded the highest single crystal yield.

The relation of the presence or absence of a semitransparent layer and the single crystal yield of quartz crucibles that were 18 inches, 24 inches, and 32 inches in size (Embodiment 4 and Comparative Example 1; Embodiment 7 and Comparative Example 2, and Embodiment 10 and Comparative Example 3) are given in FIG. 4. It will be understood that providing a semitransparent layer greatly increased the single crystal yield for all sizes.

The present invention is useful in the field of manufacturing quartz crucibles for pulling silicon single crystals.

Although the present invention has been described in considerable detail with regard to certain versions thereof, other versions are possible, and alterations, permutations and equivalents of the version shown will become apparent to those skilled in the art upon a reading of the specification and study of the drawings. Also, the various features of the versions herein can be combined in various ways to provide additional versions of the present invention. Furthermore, certain terminology has been used for the purposes of descriptive clarity, and not to limit the present invention. Therefore, any appended claims should not be limited to the description of the preferred versions contained herein and should include all such alterations, permutations, and equivalents as fall within the true spirit and scope of the present invention.

Having now fully described this invention, it will be understood to those of ordinary skill in the art that the methods of the present invention can be carried out with a wide and equivalent range of conditions, formulations, and other parameters without departing from the scope of the invention or any embodiments thereof.

All patents and publications cited herein are hereby fully incorporated by reference in their entirety. The citation of any publication is for its disclosure prior to the filing date and should not be construed as an admission that such publication is prior art or that the present invention is not entitled to antedate such publication by virtue of prior invention.

What is claimed is:

1. A silica glass crucible employed in pulling silicon single crystals wherein the crucible comprises at least a transparent layer, semitransparent layer, and opaque layer disposed from the inner surface side to the outer surface side of the crucible; content of bubbles in the transparent layer is less than 0.3 percent; content of bubbles in the semitransparent layer falls within a range of from 0.3 to 0.6 percent; and content of bubbles in the opaque layer is greater than 0.6 percent.

2. The silica glass crucible of claim 1, wherein combined thickness of the semitransparent and opaque layers falls within a range of 5 to 50 mm.

3. The silica glass crucible of claim 1, wherein combined thickness of the semitransparent and opaque layers falls within a range of 10 to 50 mm.

4. The silica glass crucible of claim 1, wherein ratio of the thicknesses of the semitransparent and opaque layers (semitransparent layer:opaque layer) falls within a range of from 5:95 to 95:5.

5. The silica glass crucible of claim 1, wherein ratio of the thicknesses of the semitransparent and opaque layers (semitransparent layer:opaque layer) falls within a range of from 15:85 to 50:50.

6. The silica glass crucible of claim 1, wherein ratio of the thicknesses of the semitransparent and opaque layers (semitransparent layer:opaque layer) falls within a range of from 20:80 to 40:60.

7. The silica glass crucible of claim 1, wherein thickness of a bottom portion in the transparent layer falls within a range of 0.5 to 10 mm.

8. The silica glass crucible of claim 1, wherein thickness of a bottom portion in the transparent layer falls within a range of 2 to 5 mm.
